(19) United States
(12) Patent Application Publication
(10) Pub. No.: US 2009/0114918 A1
(43) Pub. Date: May 7, 2009

(54) PANEL STRUCTURE AND MANUFACTURING METHOD THEREOF

(75) Inventors: Wen-Chun Wang, Taichung City (TW); Hen-Ta Kang, Taichung City (TW); Chien-Tzu Chu, Kaohsiung City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: WINTEK CORPORATION, Taichung (TW)

(21) Appl. No.: 12/265,085

(22) Filed: Nov. 5, 2008

(30) Foreign Application Priority Data
Nov. 6, 2007 (TW) 96141932

(51) Int. Cl. H01L 27/088; H01L 21/8232

(52) U.S. Cl. 257/59; 438/151; 257/E21.535; 257/E27.06

(57) ABSTRACT

A panel structure and a manufacturing method thereof are provided. The panel structure is disposed in a display device. The panel structure includes a substrate, several first transistors and second transistors. The substrate has a display circuit and a control circuit. The first transistors are disposed at the display circuit of the substrate. Each of the first transistors has a first active layer. The second transistors are disposed at the control circuit of the substrate. Each of the second transistors has a second active layer. The materials of at least one of the first active layer and the second active layer include ZnO.

This application claims the benefit of Taiwan application Serial No. 096141932, filed Nov. 6, 2007, the subject matter of which is incorporated herein by reference.

### BACKGROUND OF THE INVENTION

1. Field of the Invention

The invention relates in general to a panel structure and a manufacturing method thereof, and more particularly to a panel structure having a control circuit and a display circuit on a substrate and a manufacturing method thereof.

2. Description of the Related Art

Following the development of the technology, a display panel having a control circuit and a display circuit on the same substrate has been gradually emphasized. Each of the display circuit and the control circuit is driven by several thin film transistors (called TFT in the following). The same semi-conducting material is usually adopted to be the materials of the TFTs of the display circuit and the control circuit, such as an amorphous silicon (a-Si) material or a low temperature poly-silicon (LTPS) material.

The leakage current of a LTPS material TFT is greater than that of an a-Si material TFT. When the LTPS material TFT is applied to the display circuit, the area of the storage capacitor of the display circuit has to be increased to improve the great leakage current. However, the increase of the area of the storage capacitor reduces the aperture ratio of the display panel, so that the light utilization of the display panel decreases accordingly.

In addition, the process stability of the LTPS process is poorer and the cost of manufacturing equipment is higher. Moreover, the excimer laser technology is used to convert a a-Si material into a LTPS material to obtain the LTPS material TFT, so that the LTPS material TFT is usually lack of the uniformity after the process. Thus, the display quality of the display panel is reduced.

The electron mobility of the a-Si material TFT is approximately 0.5˜1 cm²/Vs. When the a-Si material TFT is applied to the control circuit, the dimension of the control circuit has to be accordingly increased to obtain the sufficient current. However, as the area occupied by the control circuit increases, the more space of the substrate is occupied by the control circuit to affect the disposition of other electrical elements.

### SUMMARY OF THE INVENTION

The invention is directed to a display panel and a manufacturing method thereof. ZnO is used to be one of the materials of transistors of at least one of a control circuit and a display circuit, so that the transistors have high electron mobility and the manufacturing process of the transistors is compatible with that of a-Si material TFTs.

According to the invention, a panel structure is provided. The panel structure is disposed in a display device. The panel structure includes a substrate, several first transistors and second transistors. The substrate has a display circuit and a control circuit. The first transistors are disposed at the display circuit of the substrate. Each of the first transistors has a first active layer. The second transistors are disposed at the control circuit of the substrate. Each of the second transistors has a second active layer. The materials of at least one of the first active layer and the second active layer include ZnO.

According to the invention, a manufacturing method of a panel structure is further provided. First, a substrate is provided. Then, several first transistors are formed at the substrate to constitute a display circuit, and several second transistors are formed at the substrate to constitute a control circuit. Each of the first transistors has a first active layer. Each of the second transistors has a second active layer. The materials of at least one of the first active layer and the second active layer include ZnO.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 illustrates a panel structure according to a first embodiment of the invention.

FIG. 2A is a cross-sectional view of the panel structure in FIG. 1.

FIG. 2B is a cross-sectional view of another panel structure of the first embodiment.

FIG. 3 is a flow chart of a manufacturing method of the panel structure according to the invention.

FIG. 4 is a flow chart of steps of forming the first transistor and the second transistor of the first embodiment.

FIGS. 5A˜5I illustrate the steps of forming the first transistor and the second transistor in FIG. 4.

FIG. 6 is another flow chart of steps of forming the first transistor and the second transistor of the first embodiment.

FIG. 7A is a cross-sectional view of a panel structure according to a second embodiment of the invention.

FIG. 7B is a cross-sectional view of another panel structure of the second embodiment.

FIG. 8 is a flow chart of steps of forming the first transistor and the second transistor of the second embodiment.

FIG. 9 is another flow chart of steps of forming the first transistors and the second transistor of the second embodiment.

FIG. 10A is a cross-sectional view of a panel structure according to a third embodiment of the invention.

FIG. 10B is a cross-sectional view of another panel structure of the third embodiment.

FIG. 11 is a flow chart of steps of forming the first transistor and the second transistor of the third embodiment.

FIG. 12 is another flow chart of steps of forming the first transistor and the second transistor of the third embodiment.

FIG. 13A is a cross-sectional view of a panel structure according to a fourth embodiment of the invention.

FIG. 13B is a cross-sectional view of another panel structure of the fourth embodiment.

FIG. 14 is a flow chart of steps of forming the first transistor and the second transistor of the fourth embodiment.

FIG. 15 is another flow chart of steps of forming the first transistor and the second transistor of the fourth embodiment.

### DETAILED DESCRIPTION OF THE INVENTION

A panel structure and a manufacturing method thereof are provided according to the invention. ZnO is used to be the materials of transistors of at least one of a control circuit and a display circuit, so that the transistors have high electron mobility and the manufacturing process of the transistors is compatible with that of a-Si material TFTs. Different embodiments are presented to illustrate different possible implementation forms of the invention in the following. However, the embodiments are not used to limit the invention.

### First Embodiment

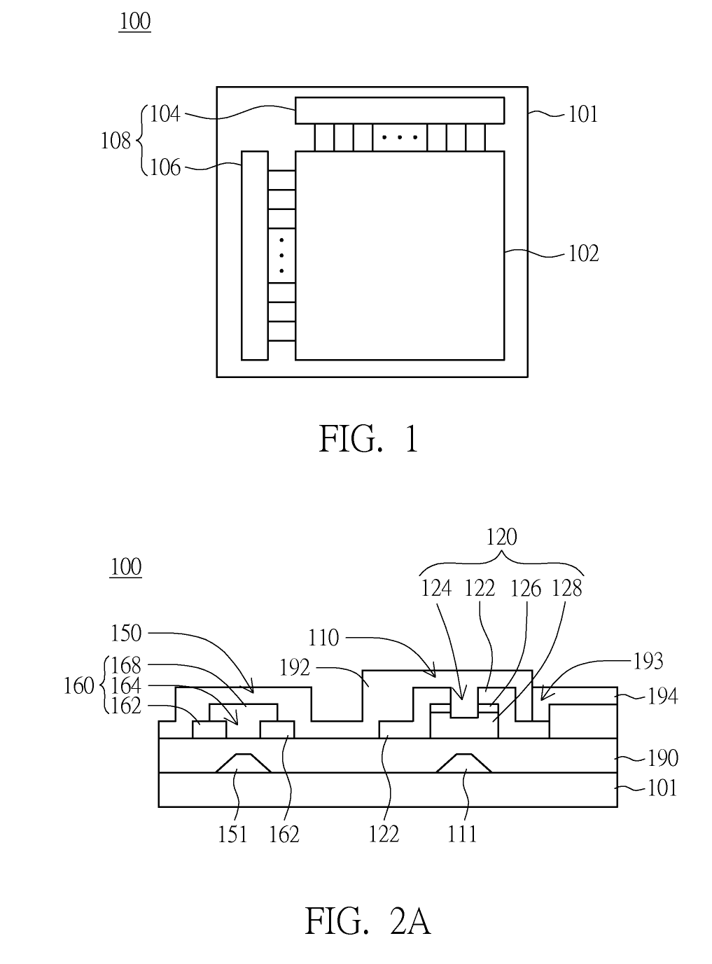

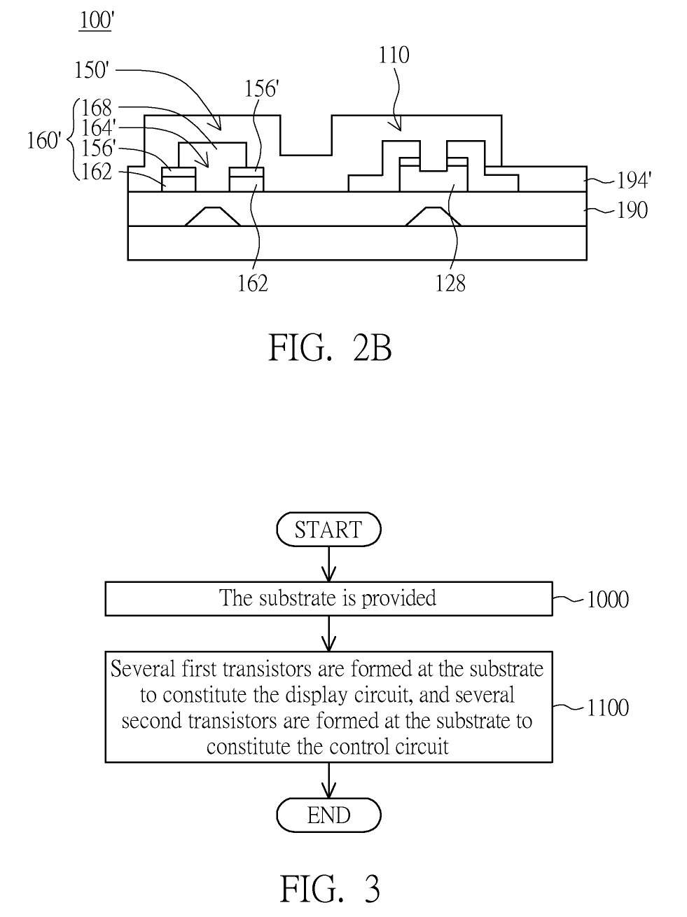

Referring to FIG. 1 and FIG. 2A at the same time, FIG. 1 illustrates a panel structure according to a first embodiment of the invention, and FIG. 2A is a cross-sectional view of the panel structure in FIG. 1. The panel structure 100 has a substrate 101, several first transistors 110 and second transistors 150. Only one first transistor 110 and one second transistor 150 are shown in FIG. 2A to simplify the figure.

The substrate 101 has a display circuit 102 and a control circuit 108. The display circuit 102 is driven by the control circuit 108 to display frames. The first transistor 110 is disposed at the display circuit 102 of the substrate 101, and the first transistor 110 has a first active layer 128. The second transistor 150 is disposed at the control circuit 108 of the substrate 101, and the second transistor 150 has a second active layer 168. The materials of at least one of the first active layer 128 and the second active layer 168 include ZnO. Therefore, at least one of the first transistor 110 and the second transistor 150 of the panel structure 100 has high electron mobility, and the manufacturing process of the transistor is compatible with that of a-Si material TFTs.

The above-mentioned panel structure 100 will be elaborated in the following. The panel structure 100 further includes several third transistors (not shown). The third transistors are disposed at the control circuit 108 of the substrate 101, and each of the third transistors has a third active layer. In the embodiment, the structures of the third transistors and the structure of the second transistor 150 are the same. Thus, only the second transistor 150 is shown and exemplified.

As shown in FIG. 1, the control circuit 108 includes a signal control circuit 104 and a scan control circuit 106. In the embodiment, the second transistor 150 and the third transistors are disposed at the control circuit 108. The second transistors are disposed at one of the signal control circuit 104 and the scan control circuit 106, and the third transistors are disposed at the other one of the signal control circuit 104 and the scan control circuit 106. While the materials of the first active layer 128 of the first transistor 110 include ZnO, the materials of both the second active layer 168 of the second transistor 150 and the third active layer of the third transistor can be ZnO or a-Si. While the materials of the second active layer 168 include ZnO, the materials of both the first active layer 128 and the third active layer can be ZnO or a-Si. The materials of the active layers can be selected according to the process demands as long as the materials of at least one of the first active layer 128 and the second active layer 168 include ZnO, so that the transistor to which the active layer belongs has high electron mobility.

As shown in FIG. 2A, the panel structure 100 includes the substrate 101, an insulation layer 190, the first transistor 110, the second transistor 150, a passivation layer 192 and a pixel electrode 194. The insulation layer 190 is disposed on the substrate 101. The first transistor 110 has a first gate 111 and a first island structure 120. The first gate 111 is disposed between the substrate 101 and the insulation layer 190. The first gate 111 corresponds to the first island structure 120. The first island structure 120 is disposed on the insulation layer 190. In the embodiment, the material of the first gate 111 is, for example, chromium (Cr), and the material of the insulation layer 190 is, for example, G-SiN.

The first island structure 120 has a first electrode layer 122, a first opening 124, a first ohm contact layer 126 and the first active layer 128. The first active layer 128 and the first ohm contact layer 126 are sequentially disposed on the insulation layer 190. A part of the first electrode layer 122 is disposed on the first ohm contact layer 126, and another part of the first electrode layer 122 is disposed on the insulation layer 190. The first opening 124 penetrates the first electrode layer 122 and the first ohm contact layer 126 and exposes the first active layer 128. In the embodiment, the material of the first active layer 128 is, for example, ZnO or a-Si, the material of the first ohm contact layer 126 is, for example, n-type a-Si, and the material of the first electrode layer 122 is, for example, Cr or aluminum (Al).

The second transistor 150 has a second gate 151 and a second island structure 160. The second gate 151 is disposed between the substrate 101 and the insulation layer 190. The second island structure 160 corresponds to the second gate 151. The second island structure 160 is disposed on the insulation layer 190. The second island structure 160 has a second electrode layer 162, a second opening 164 and the second active layer 168. The second opening 164 penetrates the second electrode layer 162. The second active layer 168 is disposed with respect to the second electrode layer 162. In the embodiment, the material of the second active layer 168 is, for example, ZnO or a-Si, the material of the second gate 151 is, for example, Cr, and the material of the second electrode layer 162 is, for example, Cr or Al. In the embodiment, the materials of the first gate 111 and the second gate 151 are the same, and the materials of the first electrode layer 122 and the second electrode layer 162 are the same.

Although the third transistor is not shown in the figures of the embodiment, the structure of the third transistor and the structure of the second transistor 150 are the same. In the embodiment, the material of the third active layer of the third transistor is, for example, ZnO or a-Si.

Furthermore, although the materials of the first active layer 128 and the second active layer 168 can be a-Si or ZnO, the materials of at least one of the first active layer 128 and the second active layer 168 have to be ZnO, so that the transistor to which the active layer belongs has high electron mobility.

In the embodiment, the second electrode layer 162 is disposed on the insulation layer 190. The second opening 164 penetrates the second electrode layer 162 and exposes the insulation layer 190. The second active layer 168 covers the second opening 164. The passivation layer 192 covers the first transistor 110 and the second transistor 150. The passivation layer 192 has a third opening 193. The pixel electrode 194 is electrically connected to the first transistor 110 via the third opening 193. In the embodiment, the material of the pixel electrode 194 is, for example, indium tin oxide (ITO).

Referring to FIG. 2A and FIG. 2B at the same time, FIG. 28 is a cross-sectional view of another panel structure of the first embodiment. The panel structure 100′ in FIG. 2B has the first transistor 110 and a second transistor 150′. A second island structure 160′ and a pixel electrode 194′ of the second transistor 150′ differ from the second island structure 160 and the pixel electrode 194 in FIG. 2A, respectively.

As shown in FIG. 2B, the second island structure 160′ of the second transistor 150′ further has a second ohm contact layer 156′ except the second electrode layer 162, a second opening 164′ and the second active layer 168. The second ohm contact layer 156′ is disposed on the second electrode layer 162, and the second opening 164′ penetrates the second ohm contact layer 156′ except the second electrode layer 162.

The second ohm contact layer 156′ is used for reducing the ohmic contact resistance of the second electrode layer 162 and the second active layer 162. In the embodiment, the material of the second ohm contact layer 156′ is, for example, ITO. In addition, the pixel electrode 194′ of the panel structure 100′ covers a part of the first transistor 110 and a part of the insulation layer 190.

Similarly, although the third transistor of the panel structure 100′ is not shown in FIG. 2B, the structure of the third transistor and the structure of the second transistor 150′ of the panel structure 100′ are also the same.

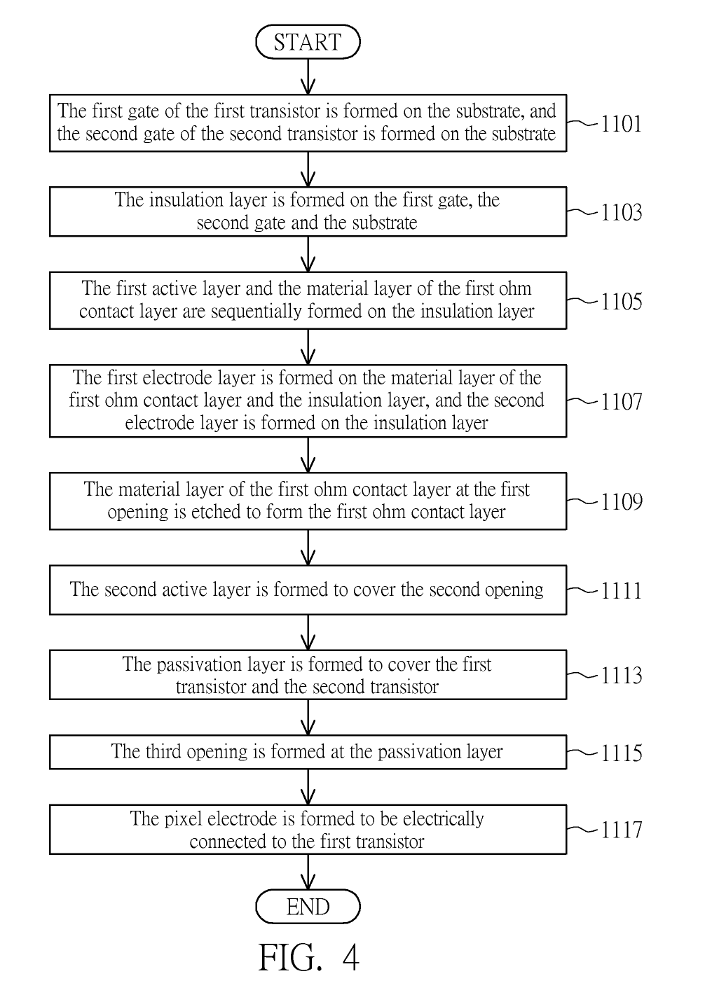

Referring to FIG. 1, FIG. 2A and FIG. 3, FIG. 3 is a flow chart of a manufacturing method of the panel structure according to the invention. The steps of the manufacturing method of the panel structure 100 are as follows. In the step 1000, the substrate 101 is provided. In the step 1100, several first transistors 110, such as shown in FIG. 2A, are formed at the substrate 101 to constitute the display circuit 102, and several second transistors 150 are formed at the substrate 101 to constitute the control circuit 108 (only one first transistor 110 and one second transistor 150 are shown in FIG. 2A).

The step 1100 further includes a step of forming several third transistors (not shown). The third transistors are disposed at the control circuit 108 of the substrate 101. Each of the third transistors has the third active layer. As the structures of the third transistors and the structures of the second transistors are the same, the manufacturing method of the panel structure 100 is only illustrated by forming the first transistor 110 and the second transistor 150.

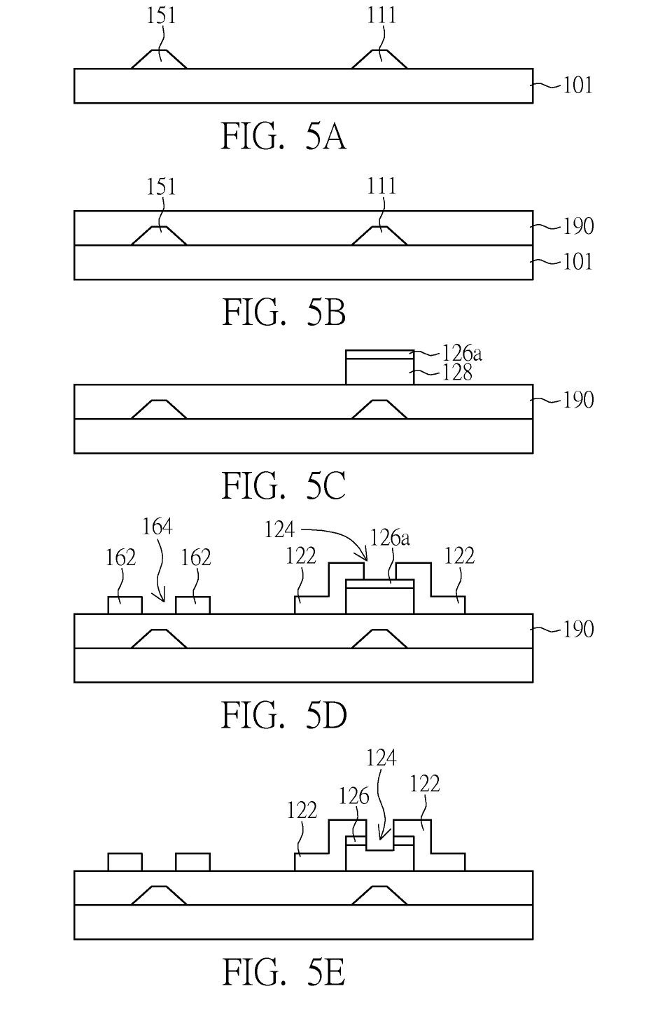

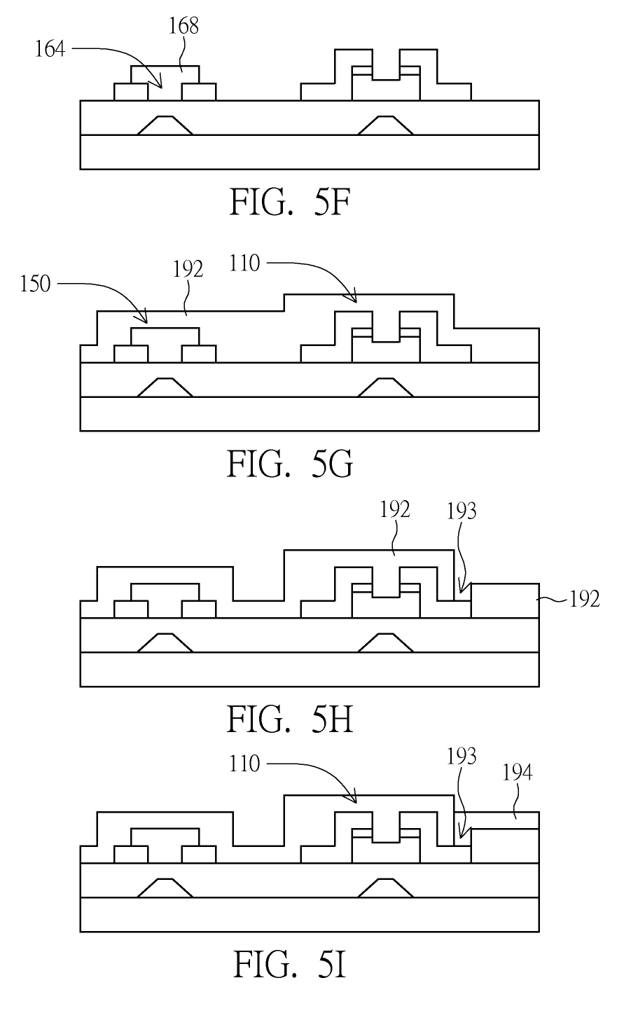

Referring FIG. 4 and FIGS. 5A˜5I at the same time, FIG. 4 is a flow chart of steps of forming the first transistor and the second transistor of the first embodiment, and FIGS. 5A˜5I illustrate the steps of forming the first transistor and the second transistor in FIG. 4. First, as shown in FIG. 4 and FIG. 5A, the first gate 111 of the first transistor 110 (as shown in FIG. 2A) is formed on the substrate 101, and the second gate 151 of the second transistor 150 (as shown in FIG. 2A) is formed on the substrate 101 in the step 1101. In the embodiment, the first gate 111 and the second gate 151 are substantially formed at the same time. A mask is used in the step 1101 to define the locations of the first gate 111 and the second gate 151, and the first gate 111 and the second gate 151 are formed by the steps of depositing, exposing, developing and etching.

Then, as shown in FIG. 4 and FIG. 5B, the insulation layer 190 is formed on the first gate 111, the second gate 151 and the substrate 101 in the step 1103. After that, as shown in FIG. 4 and FIG. 5C, the first active layer 128 and a material layer 126a of the first ohm contact layer are sequentially formed on the insulation layer 190 in the step 1105. A mask is used in the step 1105 to define the locations of the first active layer 128 and the material layer 126a of the first ohm contact layer, and the first active layer 128 and the material layer 126a of the first ohm contact layer are formed by the steps of depositing, exposing, developing and etching.

Then, as shown in FIG. 4 and FIG. 5D, the first electrode layer 122 is formed on the material layer 126a of the first ohm contact layer and the insulation layer 190, and the second electrode layer 162 is formed on the insulation layer 190 in the step 1107. A mask is used in the step 1107 to define the locations of the first electrode layer 122 and the second electrode layer 162, and the first electrode layer 122 and the second electrode layer 162 are formed by the steps of depositing, exposing, developing and etching. The first electrode layer 122 has the first opening 124, and the second electrode layer 162 has the second opening 164.

After that, as shown in FIG. 4 and FIG. 5E, the material layer 126a of the first ohm contact layer at the first opening 124 is etched to form the first ohm contact layer 126 in the step 1109. The steps of depositing, exposing, developing and etching are used in the step 1109 to form the first ohm contact layer 126.

Then, as shown in FIG. 4 and FIG. 5F, the second active layer 168 is formed to cover the second opening 164 in the step 1111. A mask is used in the step 1111 to define the location of the second active layer 168, and the second active layer 168 is formed by the steps of depositing, exposing, developing and etching.

Then, as shown in FIG. 4 and FIG. 5G, the passivation layer 192 is formed to cover the first transistor 110 and the second transistor 150 in the step 1113. After that, as shown in FIG. 4 and FIG. 5H, the third opening 193 is formed at the passivation layer 192 in the step 1115. A mask is used in the step 1115 to define the location of the third opening 193, and the third opening 193 is formed by the steps of depositing, exposing, developing and etching.

Then, as shown in FIG. 4 and FIG. 5I, the pixel electrode 194 is formed to be electrically connected to the first transistor 110 in the step 1117. The pixel electrode 194 is electrically connected to the first transistor 110 via the third opening 193. A mask is used in the step 1117 to define the location of the pixel electrode 194, and the pixel electrode 194 is formed by the steps of depositing, exposing, developing and etching. The manufacturing method of the panel structure 100 of the embodiment is illustrated.

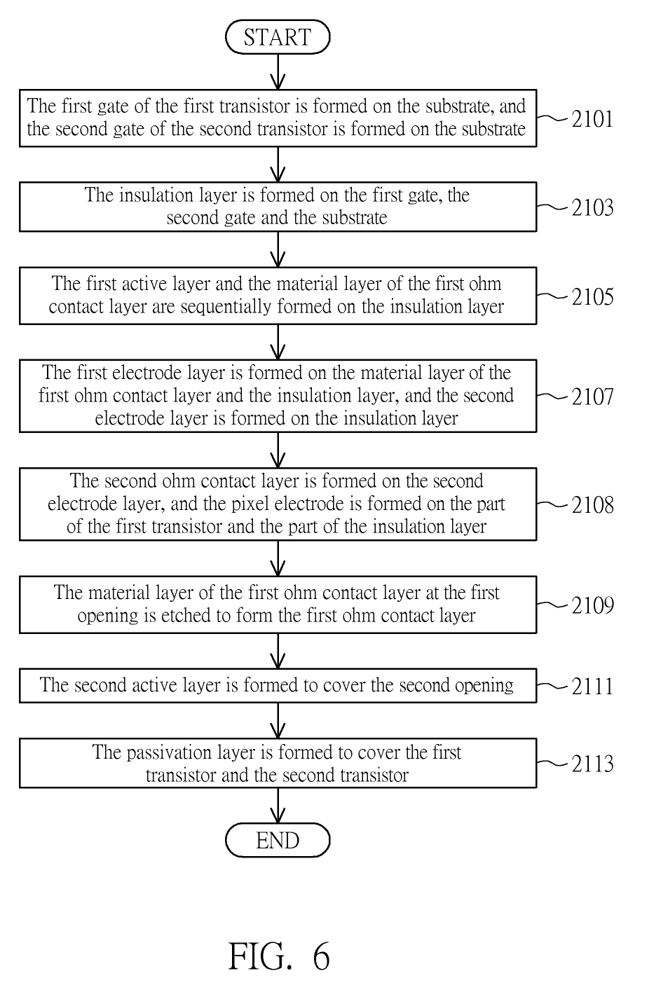

Referring to FIG. 2B and FIG. 6, FIG. 6 is another flow chart of steps of forming the first transistor and the second transistor of the first embodiment. As the steps 2101 to 2107 in FIG. 6 and the steps 1101 to 1107 in FIG. 4 are the same, the steps 2101 to 2107 are not repeatedly described herein. As shown in FIG. 6, the step 2108 is after the step 2107. The step 2108 is to form the second ohm contact layer 156′ on the second electrode layer 162 and to form the pixel electrode 194′ on the part of the first transistor 110 and the part of the insulation layer 190. A mask is used in the step 2108 to define the locations of the second ohm contact layer 156′ and the pixel electrode 194′, and the second ohm contact layer 156′ and the pixel electrode 194′ are formed by the steps of depositing, exposing, developing and etching. The second ohm contact layer 156′ is capable of reducing the ohmic contact resistance of the second electrode layer 162 and the second active layer 168.

As shown in FIG. 6, the steps 2109 to 2113 are performed to form the panel structure 100′ after the step 2108. The steps 2109 to 2113 are the same with the steps 1109 to 1113 in FIG. 4. In addition, as the pixel electrode 194′ is formed in the step 2108 and the panel structure 100′ does not have the third opening 193 shown in FIG. 2A, the panel structure 100′ is obtained after the step 2113 is performed. The manufacturing method of the panel structure 100′ is illustrated.

In the embodiment, the materials of at least one of the first active layer 128 and the second active layer 168 include ZnO. While the materials of the first active layer 128 include ZnO, the materials of both the second active layer 168 and the third active layer can be a-Si or ZnO. While the materials of the second active layer 168 include ZnO, the materials of both the first active layer 128 and the third active layer can be a-Si or ZnO. As long as the materials of at least one of the first active layer 128 and the second active layer 168 of the panel structure 100′ include ZnO, the transistor to which the active layer belongs has high electron mobility. Of course, ZnO can be adopted to be the materials of the first active layer 128, the second active layer 168 and the third active layer of the panel structures 100 and 100′ in practice so as to increase the electron mobility of the whole panel structures 100 and 100′

In the embodiment, the materials of at least one of the first active layer and the second active layer of the panel structure include ZnO, so that the transistor to which the active layer belongs has high electron mobility. As the higher electron mobility of the transistor results in the smaller dimension of the transistor, the implementation of the embodiment can shrink the dimension of the transistor with ZnO. Therefore, the dimension of the panel structure is shrunk accordingly to satisfy the demand for electronic devices to be light, thin and compact. In addition, the panel structures 100 and 100′ of the embodiment provide different implementation modes to satisfy different process demands.

### Second Embodiment

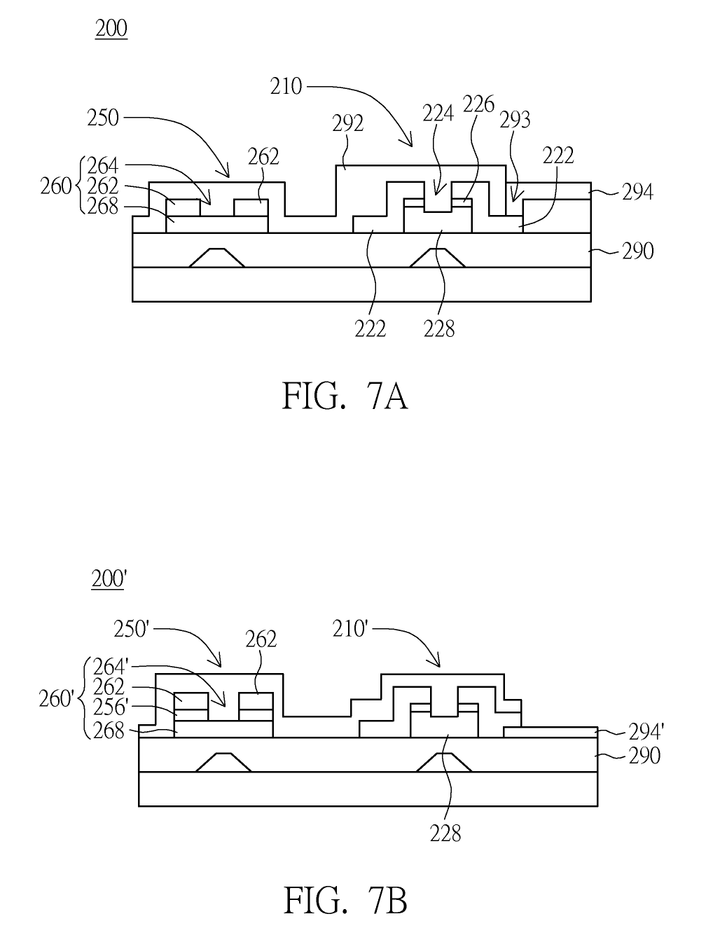

Referring to FIG. 7A, a cross-sectional view of a panel structure according to a second embodiment of the invention is illustrated. A second island structure 260 of the panel structure 200 in FIG. 7A and the second island structure 160 of the panel structure 100 in FIG. 2A are different. Although the second island structure 260 of the panel structure 200 has a second electrode layer 262, a second opening 264 and a second active layer 268 as well, the second active layer 268 is disposed on an insulation layer 290. The second electrode layer 262 is disposed above the second active layer 268, and the second opening 264 penetrates the second electrode layer 262 to expose the second active layer 268.

In order to simplify the figure, only one first transistor 210 and one second transistor 250 are illustrated in FIG. 7A. However, as stated early, the panel structure 200 differs from the panel structure 100 (as shown in FIG. 2A) only in the second island structure 260. Thus, the panel structure 200 also includes several first transistors 210, second transistors 250 and third transistors (not shown). In the embodiment, the materials of at least one of a first active layer 228 and the second active layer 268 include ZnO. While the material of the first active layer 228 is ZnO, the materials of both the second active layer 268 and a third active layer of the third transistor can be a-Si or ZnO. While the materials of the second active layer 268 include ZnO, the materials of both the first active layer 228 and the third active layer can be a-Si or ZnO.

Referring to FIG. 7A and FIG. 7B at the same time, FIG. 7B is a cross-sectional view of another panel structure of the second embodiment. A second transistor 250′ and a pixel electrode 294′ of the panel structure 200′ in FIG. 7B differ from those of the panel structure 200 in FIG. 7A. As shown in FIG. 7B, a second island structure 260′ of the second transistor 250′ further has a second ohm contact layer 256′ except the second electrode layer 264, a second opening 264′ and the second active layer 268. The second ohm contact layer 256′ is disposed between the second active layer 268 and the second electrode layer 262. The second opening 264′ penetrates the second ohm contact layer 256′ and the second electrode layer 262.

In the embodiment, the material of the second ohm contact layer 256′ is, for example, ITO. The second ohm contact layer 256′ is used for reducing the ohmic contact resistance of the second electrode layer 262 and the second active layer 268. In addition, the pixel electrode 294′ of the panel structure 200′ is disposed on a part of the insulation layer 290, and the first transistor 210′ covers a part of the pixel electrode 294′. Similarly, third transistors of the panel structure 200′ are not shown in FIG. 7B. As the structures of the third transistors and the structure of the second transistor 250′ of the panel structure 200′ are the same, only the second transistor 250′ is exemplified herein.

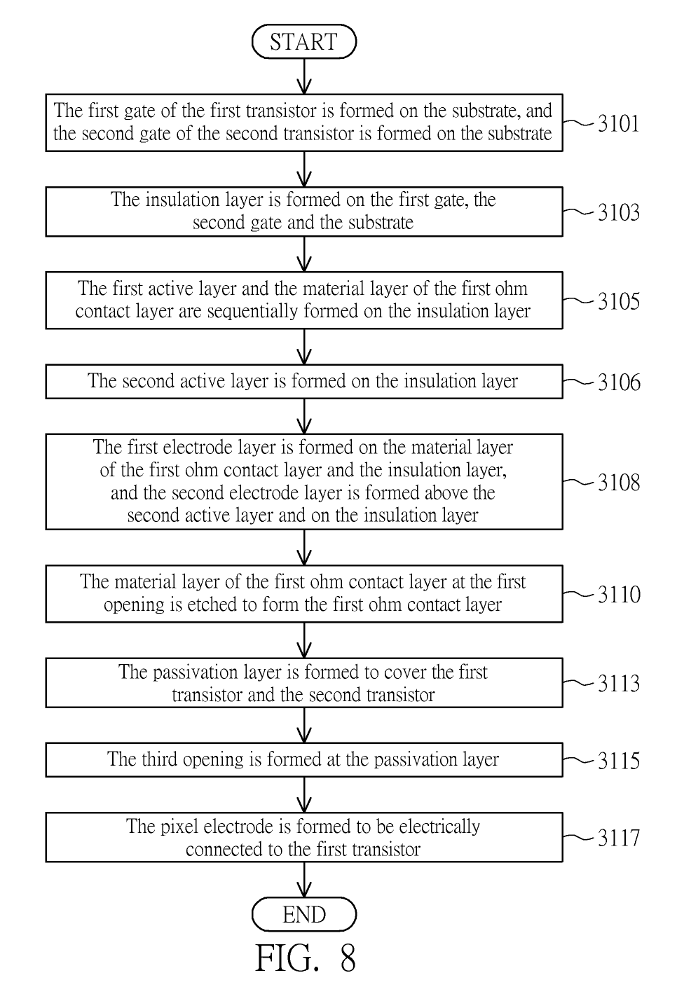

The panel structure 200 shown in FIG. 7A is formed by the manufacturing method in FIG. 3. The manufacturing method of the panel structure 200 of the embodiment is only exemplified by the first transistor 210 and the second transistor 250. The step 1100 in FIG. 3 for the panel structure 200 is shown in FIG. 8. Referring to FIG. 7A and FIG. 8 at the same time, FIG. 8 is a flow chart of steps of forming the first transistor and the second transistor of the second embodiment. The steps 3101 to 3105 in FIG. 8 are the same with the steps 1101 to 1105 in FIG. 4, respectively, and the steps 3101 to 305 are not repeatedly described herein. As shown in FIG. 8, the step 3106 is after the step 3105. The step 3106 is to form the second active layer 268 on the insulation layer 290. A mask is used in the step 3106 to define the location of the second active layer 268, and the second active layer 268 is formed by the steps of depositing, exposing, developing and etching.

Then, in the step 3108, a first electrode layer 222 is formed on a material layer of a first ohm contact layer 226 and the insulation layer 290, and the second electrode layer 262 is formed above the second active layer 268 and on the insulation layer 290. A mask is used in the step 3108 to define the locations of the first electrode layer 222 and the second electrode layer 262, and the first electrode layer 222 and the second electrode layer 262 are formed by the steps of depositing, exposing, developing and etching. The first electrode layer 222 has a first opening 224, and the second electrode layer 262 has the second opening 264.

After that, in the step 3110, the material layer of the first ohm contact layer 226 at the first opening 224 is etched to form the first ohm contact layer 226. The first ohm contact layer 226 is formed by the steps of depositing, exposing, developing and etching in the step 3110.

As shown in FIG. 8, the steps 3113, 3115 and 3117 are performed after the step 3110 to form a passivation layer 292, a third opening 293 and a pixel electrode 294, respectively. As the steps 3113, 3115 and 3117 are respectively the same with the steps 1113, 1115 and 1117 in FIG. 4, the steps 3113, 3115 and 3117 are not repeatedly described herein. The manufacturing method of the panel structure 200 of the embodiment is illustrated.

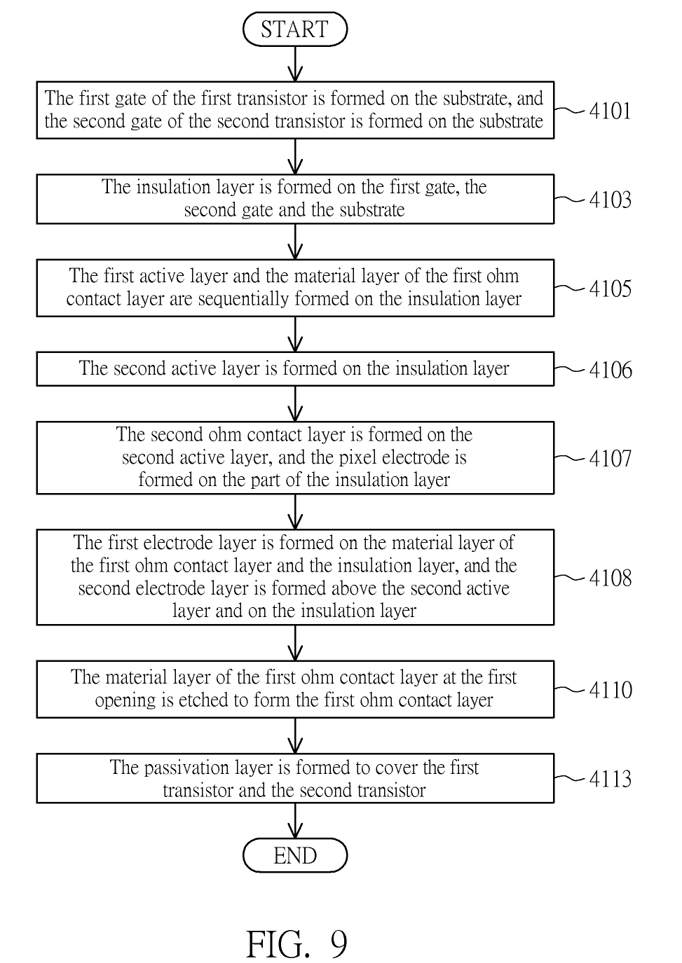

The manufacturing method of the panel structure 200′ is shown in FIG. 3. The step 1100 in FIG. 3 for the panel structure 200′ is shown in FIG. 9. Referring to FIG. 7B and FIG. 9 at the same time, FIG. 9 is another flow chart of steps of forming the first transistor and the second transistor of the second embodiment. The steps 4101 to 4106 in FIG. 9 are respectively the same with the steps 3101 to 3106 in FIG. 8, and the steps 4101 to 4106 are not repeatedly described herein. As shown in FIG. 9, the step 4107 is after the step 4106. The step 4107 is to form the second ohm contact layer 256′ on the second active layer 268 and to form the pixel electrode 294′ on the part of the insulation layer 290. A mask is used in the step 4107 to define the locations of the second ohm contact layer 256′ and the pixel electrode 294′, and the second ohm contact layer 256′ and the pixel electrode 294′ are formed by the steps of depositing, exposing, developing and etching. The second ohm contact layer 256′ can reduce the ohmic contact resistance of the second electrode layer 262 and the second active layer 268.

As shown in FIG. 9, the steps 4108, 4110 and 4113 are performed after the step 4107. The steps 4108, 4110 and 4113 are respectively the same with the steps 3108, 3110 and 3113 in FIG. 8, and the steps 4108, 4110 and 4113 are not repeatedly described herein. In addition, as the pixel electrode 294′ is formed in the step 4107 and the panel structure 200′ in FIG. 7B does not have the third opening 293 shown in FIG. 7A, the panel structure 200′ is obtained after the step 4113 is performed. The manufacturing method of the panel structure 200′ is illustrated.

Although only one first transistor 210′ and one second transistor 250′ are shown in FIG. 7B to simplify the figure, the panel structure 200′ has several first transistors 210′, second transistors 250′ and third transistors. As the structure of the second transistor 250′ and the structure of the third transistor are the same, only the second transistor 250′ is exemplified herein. The materials of at least one of the first active layer 228 and the second active layer 268 of the panel structure 200′ include ZnO. While the materials of the first active layer 228 include ZnO, the materials of both the second active layer 268 and the third active layer can be a-Si or ZnO. While the materials of the second active layer 268 include ZnO, the materials of both the first active layer 228 and the third active layer can be ZnO or a-Si. As long as the materials of at least one of the first active layer 228 and the second active layer 268 include ZnO, the transistor to which the active layer belongs has high electron mobility. Of course, ZnO can be adopted to be the materials of the first active layer 228, the second active layer 268 and the third active layer of the panel structures 200 and 200′ in practice so as to increase the electron mobility of the whole panel structures 200 and 200′.

In the embodiment, the materials of at least one of the first active layer and the second active layer of the panel structure include ZnO, so that the transistor to which the active layer belongs has high electron mobility. As the higher electron mobility of the transistor results in the smaller dimension of the transistor, the implementation of the embodiment can shrink the dimension of the transistor with ZnO. Therefore, the dimension of the panel structure is shrunk accordingly to satisfy the demand for electronic devices to be light, thin and compact. In addition, the panel structures 200 and 200′ of the embodiment provide implementation modes to satisfy different process demands.

### Third Embodiment

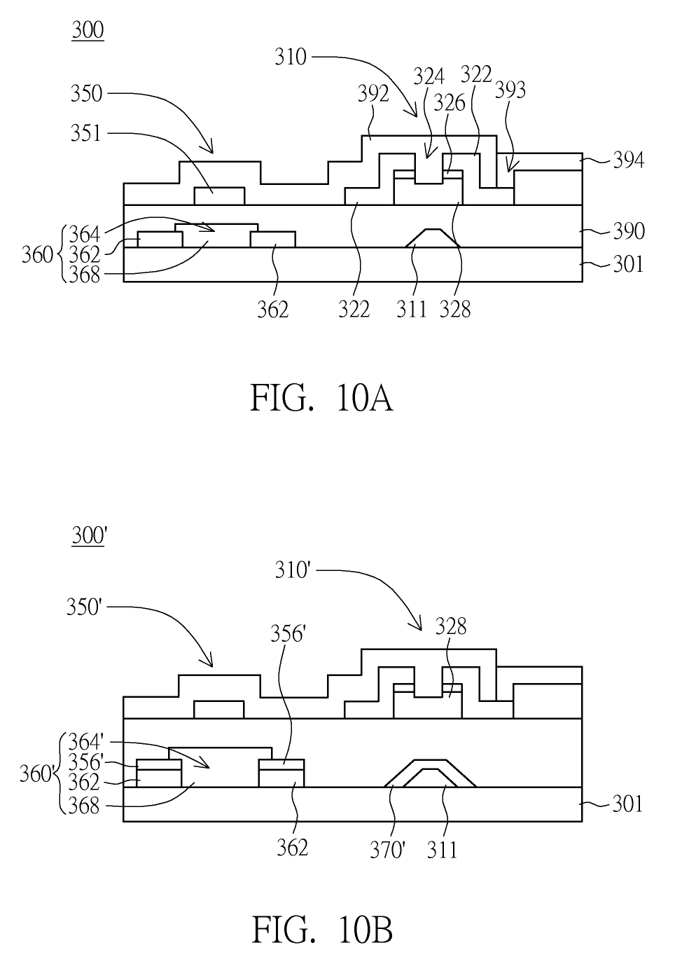

Referring to FIG. 10A, a cross-sectional view of a panel structure according to a third embodiment of the invention is illustrated. A second transistor 350 of the panel structure 300 in FIG. 10A differs from the second transistor 150 of the panel structure 100 in FIG. 2A. Although the second transistor 350 has a second gate 351 and a second island structure 360 as well, the second gate 351 is disposed on an insulation layer 390 and the second island structure 360 is disposed between the insulation layer 390 and a substrate 301.

The second island structure 360 similarly has a second electrode layer 362, a second opening 364 and a second active layer 368. The second electrode layer 362 is disposed on the substrate 301. The second opening 364 penetrates the second electrode layer 362 to expose the substrate 301. The second active layer 368 covers the second opening 364.

In the embodiment, the panel structure 300 includes several first transistors 310, second transistors 350 and third transistors (not illustrated). However, only one first transistor 310 and one second transistor 350 are illustrated in FIG. 10A to simplify the figure. As the structure of the second transistor 350 and the structure of the third transistor are the same, only the second transistor 350 is exemplified herein. The materials of at least one of a first active layer 328 of the first transistor 310 and the second active layer 368 of the second transistor 350 include ZnO. While the materials of the first active layer 328 include ZnO, the materials of both the second active layer 368 and the third active layer can be a-Si or ZnO. While the materials of the second active layer 368 include ZnO, the materials of both the first active layer 328 and the third active layer can be ZnO or a-Si. As long as the materials of at least one of the first active layer 328 and the second active layer 368 include ZnO, the transistor to which the active layer belongs has high electron mobility.

Referring to FIG. 10A and FIG. 10B at the same time, FIG. 10B is a cross-sectional view of another panel structure of the third embodiment. A second island structure 360′ of a second transistor 350′ further has a second ohm contact layer 356′ except the second electrode layer 362, a second opening 364′ and the second active layer 368. The second ohm contact layer 356′ is disposed on the second electrode layer 362. The second opening 364′ penetrates the second ohm contact layer 356′ and the second electrode layer 362. In the embodiment, the material of the second ohm contact layer 356′ is, for example, ITO. The second ohm contact layer 356′ is used for reducing the ohmic contact resistance of the second electrode layer 362 and the second active layer 368.

In addition, a metal oxidation layer 370′ is disposed on a first gate 311 of a first transistor 310′. The materials of the metal oxidation layer 370′ and the second ohm contact layer 356′ are the same, such as ITO. In the embodiment, the metal oxidation layer 370′ and the second ohm contact layer 356′ are substantially formed at the same time. Similarly, although a third transistor of the panel structure 300′ is not shown in FIG. 10B, the structure of the third transistor and the structure of the second transistor 350′ of the panel structure 300′ are the same.

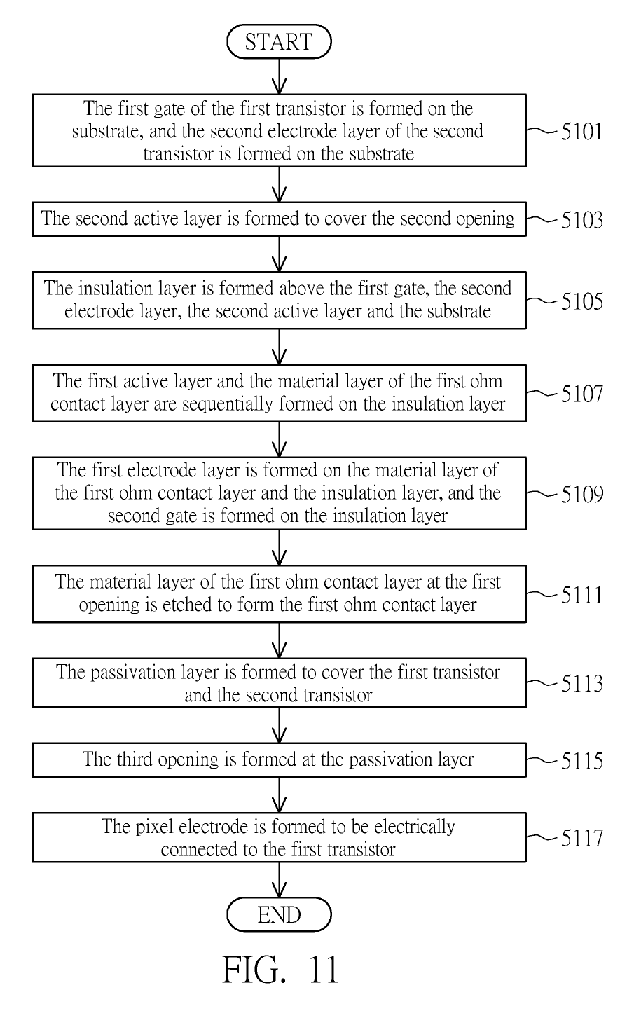

The panel structure 300 in FIG. 10A is formed by the manufacturing method in FIG. 3. The step 1100 in FIG. 3 for the panel structure 300 is illustrated in FIG. 11. Referring to FIG. 10A and FIG. 11 at the same time, FIG. 11 is a flow chart of steps of forming the first transistor and the second transistor of the third embodiment. First, in the step 5101, the first gate 311 of the first transistor 310 is formed on the substrate 301, and the second electrode layer 362 of the second transistor 350 is formed on the substrate 301. A mask is used in the step 5101 to define the locations of the first gate 311 and the second electrode layer 362, and the first gate 311 and the second electrode layer 362 are formed by the steps of depositing, exposing, developing and etching. The second electrode layer 362 has the second opening 364.

Then, in the step 5103, the second active layer 368 is formed to cover the second opening 364. A mask is used in the step 5103 to define the location of the second active layer 368, and the second active layer 368 is formed by the steps of depositing, exposing, developing and etching.

After that, in the step 5105, the insulation layer 390 is formed above the first gate 311, the second electrode layer 362, the second active layer 368 and the substrate 301. Then, in the step 5107, the first active layer 328 and a material layer of a first ohm contact layer 326 are sequentially formed on the insulation layer 390. A mask is used in the step 5107 to define the locations of the first active layer 328 and the material layer of the first ohm contact layer 326, and the first active layer 328 and the material layer of the first ohm contact layer 326 are formed by the steps of depositing, exposing, developing and etching.

Then, in the step 5109, a first electrode layer 322 is formed on the material layer of the first ohm contact layer 326 and the insulation layer 390, and the second gate 351 is formed on the insulation layer 390. A mask is used in the step 5109 to define the locations of the first electrode layer 322 and the second gate 351, and the first electrode layer 322 and the second gate 351 are formed by the steps of depositing, exposing, developing and etching. The first electrode layer 322 has a first opening 324.

After that, in the step 5111, the material layer of the first ohm contact layer 326 at the first opening 324 is etched to form the first ohm contact layer 326. The steps of depositing, exposing, developing and etching are used in the step 5111 to form the first ohm contact layer 326.

Then, in the step 5113, a passivation layer 392 is formed to cover the first transistor 310 and the second transistor 350. After that, in the step 5115, a third opening 393 is formed at the passivation layer 392. A mask is used in the step 5115 to define the location of the third opening 393, and the third opening 393 is formed by the steps of depositing, exposing, developing and etching.

After that, in the step 5117, a pixel electrode 394 is formed to be electrically connected to the first transistor 310. The pixel electrode 394 is electrically connected to the first transistor 310 via the third opening 393. A mask is used in the step 5117 to define the location of the pixel electrode 394, and the pixel electrode 394 is formed by the steps of depositing, exposing, developing and etching. The manufacturing method of the panel structure 300 of the embodiment is illustrated.

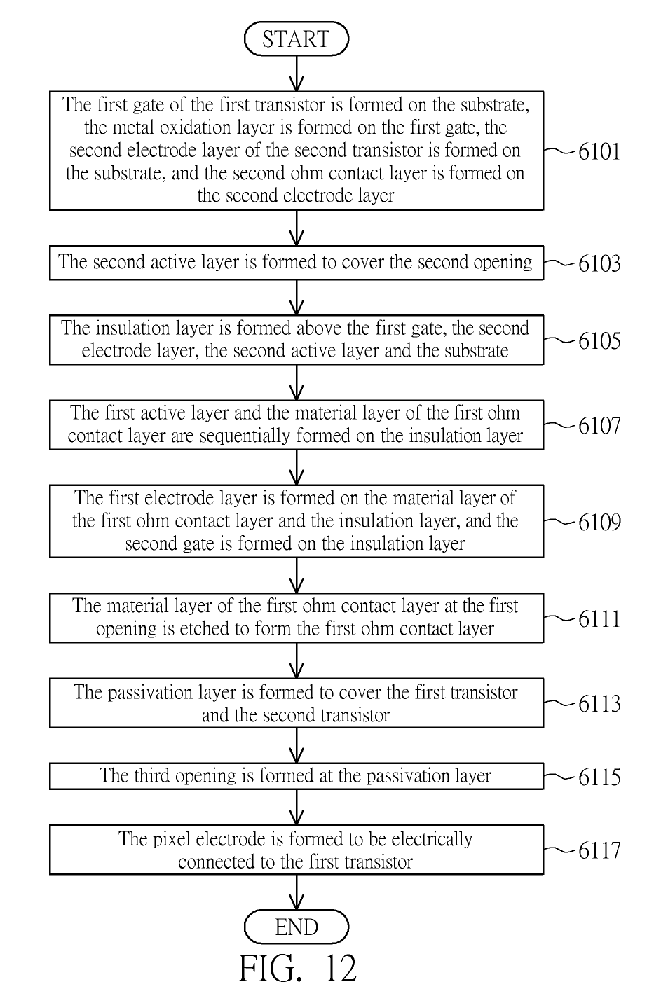

Referring to FIG. 10B and FIG. 12 at the same time, FIG. 12 is another flow chart of steps of forming the first transistor and the second transistor of the third embodiment. As shown in FIG. 12, the step 6101 is to form the first gate 311 of the first transistor 310′ on the substrate 301 and to form the metal oxidation layer 370′ on the first gate 311. The second electrode layer 362 of the second transistor 350′ is formed on the substrate 301, and the second ohm contact layer 356′ is formed on the second electrode layer 362 in the step 6101 as well. A mask is used in the step 6101 to define the locations of the first gate 311, the metal oxidation layer 370′, the second electrode layer 362 and the second ohm contact layer 356′, and the first gate 311, the metal oxidation layer 370′, the second electrode layer 362 and the second ohm contact layer 356′ are formed by the steps of depositing, exposing, developing and etching.

As shown in FIG. 12, the steps 6103 to 6117 are after the step 6101 to form the panel structure 300′. As the steps 6103 to 6117 in FIG. 12 are the same with the steps 5103 to 5117 in FIG. 11, the steps 6103 to 6117 are not repeatedly described herein. The manufacturing method of the panel structure 300′ is illustrated. Although only one first transistor 310′ and one second transistor 350′ are illustrated in FIG. 10B to simplify the figure, the panel structure 300′ includes several first transistors 310′, second transistors 350′ and third transistors. As the structure of the third transistor and the structure of the second transistor 350′ are the same, only the second transistor 350′ is exemplified herein.

The materials of at least one of the first active layer 328 and the second active layer 368 of the panel structure 300′ include ZnO. While the materials of the first active layer 328 include ZnO, the materials of both the second active layer 368 and a third active layer of the third transistor can be ZnO or a-Si. While the materials of the second active layer 368 include ZnO, the materials of both the first active layer 328 and the third active layer can be ZnO or a-Si. As long as the materials of at least one of the first active layer 328 and the second active layer 368 include ZnO, the transistor to which the active layer belongs has high electron mobility. Of course, ZnO can be adopted to be the materials of the first active layer 328, the second active layer 368 and the third active layer so as to increase the electron mobility of the whole panel structures 300 and 300′.

In the embodiment, the materials of at least one of the first active layer and the second active layer of the panel structure include ZnO, so that the transistor to which the active layer belongs has high electron mobility. As the higher electron mobility of the transistor results in the smaller dimension of the transistor, the implementation of the embodiment can shrink the dimension of the transistor with ZnO. Therefore, the dimension of the panel structure is shrunk accordingly to satisfy the demand for electronic devices to be light, thin and compact. In addition, the panel structures 300 and 300′ of the embodiment provide different implementation modes to satisfy different process demands.

### Fourth Embodiment

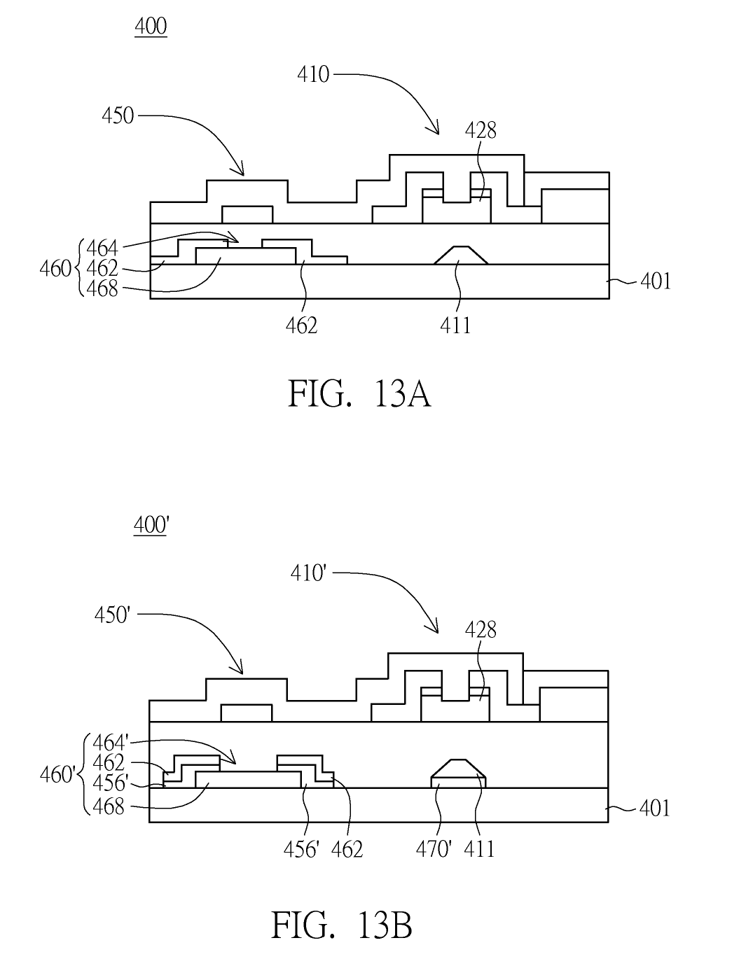

Referring to FIG. 13A, a cross-sectional view of a panel structure according to a fourth embodiment of the invention is illustrated. A second island structure 460 of the panel structure 400 in FIG. 13A differs from the second island structure 360 of the panel structure 300 in FIG. 10A. Although the second island structure 460 of the panel structure 400 has a second electrode layer 462, a second opening 464 and a second active layer 468 as well, the second active layer 468 is disposed on a substrate 401. The second electrode layer 462 is disposed on a part of the second active layer 468 and a part of the substrate 401. The second opening 464 penetrates the second electrode layer 462 to expose the second active layer 468.

In the embodiment, the panel structure 400 has several first transistors 410, second transistors 450 and third transistors (not shown). Only one first transistor 410 and one second transistor 450 are illustrated in FIG. 13A to simplify the figure. As the structure of the second transistor 450 and the structure of the third transistor are the same, only the second transistor 450 is exemplified herein. The materials of at least one of the first active layer 428 of the first transistor 410 and the second active layer 468 of the second transistor 450 include ZnO. While the materials of the first active layer 428 include ZnO, the materials of both the second active layer 468 and a third active layer of the third transistor can be ZnO or a-Si. While the materials of the second active layer 468 include ZnO, the materials of both the first active layer 428 and the third active layer can be ZnO or a-Si. As long as the materials of at least one of the first active layer 428 and the second active layer 468 include ZnO, the transistor to which the active layer belongs has high electron mobility.

Referring to FIG. 13A and FIG. 13B at the same time, FIG. 13B is a cross-sectional view of another panel structure of the fourth embodiment. A second island structure 460′ of a second transistor 450′ further has a second ohm contact layer 456′ except the second electrode layer 462, a second opening 464′ and the second active layer 468. The second ohm contact layer 456′ is disposed between the second active layer 468 and the second electrode layer 462. The second opening 464′ penetrates the second ohm contact layer 456′ and the second electrode layer 462. In the embodiment, the material of the second ohm contact layer 456′ is, for example, ITO. The second ohm contact layer 456′ is used for reducing the ohmic contact resistance of the second electrode layer 462 and the second active layer 468.

In addition, a metal oxidation layer 470′ is disposed between a first gate 411 and the substrate 401. The material of the metal oxidation layer 470′ is the same with that of the second ohm contact layer 456′, such as ITO. In the embodiment, the metal oxidation layer 470′ and the second ohm contact layer 456′ are substantially formed at the same time. Similarly, although third transistors of the panel structure 400′ are not shown in FIG. 13B, the structure of the third transistor and the structure of the second transistor 450′ of the panel structure 400′ are the same.

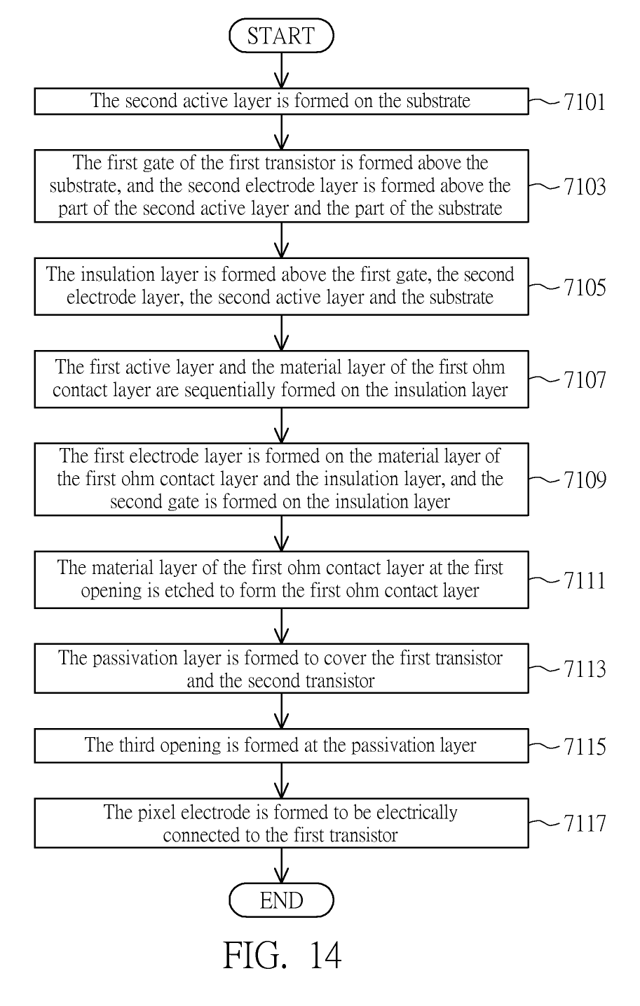

The panel structure 400 in FIG. 13A is formed by the manufacturing method in FIG. 3. The step 1100 in FIG. 3 for the panel structure 400 is illustrated in FIG. 14. Referring to FIG. 13A and FIG. 14 at the same time, FIG. 14 is a flow chart of steps of forming the first transistor and the second transistor of the fourth embodiment. First, in the step 7101, the second active layer 468 is formed on the substrate 401. A mask is used in the step 7101 to define the location of the second active layer 468, and the second active layer 468 is formed by the steps of depositing, exposing, developing and etching.

Then, in the step 7103, the first gate 411 of the first transistor 410 is formed above the substrate 401, and the second electrode layer 462 is formed above the part of the second active layer 468 and the part of the substrate 401. A mask is used in the step 7103 to define the locations of the first gate 411 and the second electrode layer 462, the first gate 411 and the second electrode layer 462 are formed by the steps of depositing, exposing, developing and etching. The second electrode layer 462 has the second opening 464.

As shown in FIG. 14, the steps 7105 to 7117 are after the step 7103. As the steps 7105 to 7117 in FIG. 14 are the same with the steps 5105 to 5117 in FIG. 11, the steps 7105 to 7117 are not repeatedly described herein. The manufacturing method of the panel structure 400 of the embodiment is illustrated.

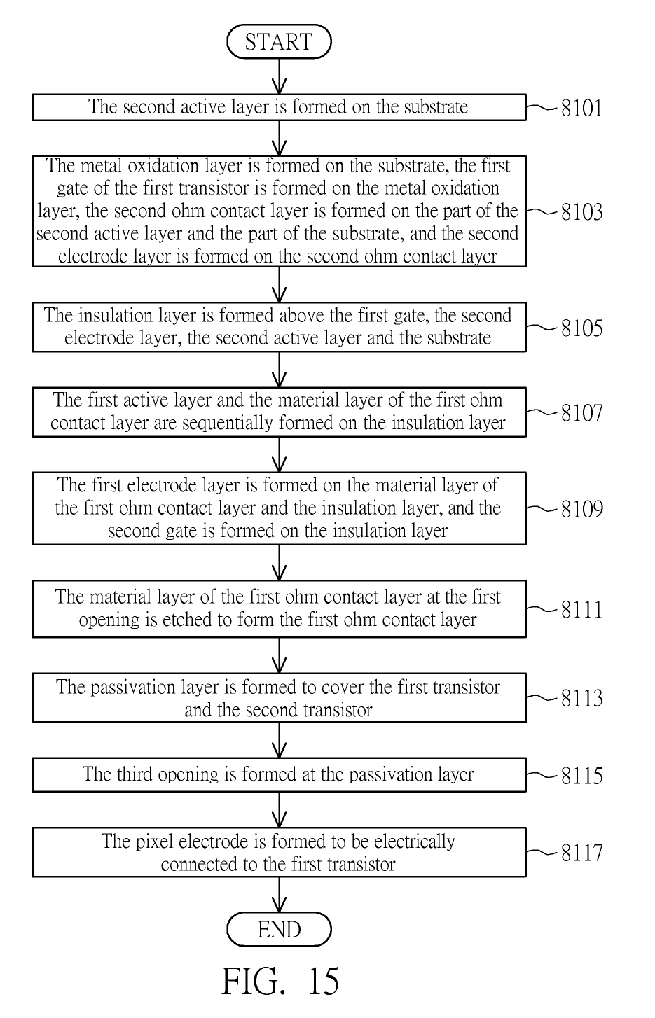

Referring to FIG. 13B and FIG. 15 at the same time, FIG. 15 is another flow chart of steps of forming the first transistor and the second transistor of the fourth embodiment. The step 8101 in FIG. 15 is the same with the step 7101 in FIG. 14, and the step 8101 is not repeatedly described herein. As shown in FIG. 15, the step 8103 is after the step 8101. The step 8103 is to form the metal oxidation layer 470′ on the substrate 401, to form the first gate 411 of the first transistor 410′ on the metal oxidation layer 470′, to form the second ohm contact layer 456′ on a part of the second active layer 468 and a part of the substrate 401 and to form the second electrode layer 462 on the second ohm contact layer 456′. A mask is used in the step 8103 to define the locations of the first gate 411, the metal oxidation layer 470′, the second electrode layer 462 and the second ohm contact layer 456′, and the first gate 411, the metal oxidation layer 470′, the second electrode layer 462 and the second ohm contact layer 456′ are formed by the steps of depositing, exposing, developing and etching.

As shown in FIG. 15, the steps 8105 to 8117 are after the step 8103. As the steps 8105 to 8117 in FIG. 15 are the same with the steps 7105 to 7117 in FIG. 14, the steps 8105 to 8117 are not repeatedly described herein. The manufacturing method of the panel structure 400′ is illustrated. Although only one first transistor 410′ and one second transistor 450′ are illustrated in FIG. 13B to simplify the figure, the panel structure 400′ includes several first transistors 410′, second transistors 450′ and third transistors (not shown). As the structure of the third transistor and the structure of the second transistor 450′ are the same, only the second transistor 450′ is exemplified herein.

The materials of at least one of the first active layer 428 and the second active layer 468 of the panel structure 400′ include ZnO. While the materials of the first active layer 428 include ZnO, the materials of both the second active layer 468 and a third active layer of the third transistor can be ZnO or a-Si. While the materials of the second active layer 468 include ZnO, the materials of both the first active layer 428 and the third active layer can be ZnO or a-Si. As long as the materials of at least one of the first active layer 428 and the second active layer 428 of the panel structure 400′ include ZnO, the transistor to which the active layer belongs has high electron mobility. Of course, ZnO can be adopted to be the materials of the first active layer 428, the second active layer 468 and the third active layer so as to increase the electron mobility of the whole panel structures 400 and 400′.

In the embodiment, the materials of at least one of the first active layer and the second active layer of the panel structure include ZnO, so that the transistor to which the active layer belongs has high electron mobility. As the higher electron mobility of the transistor results in the smaller dimension of the transistor, the implementation of the embodiment can shrink the dimension of the transistor with ZnO. Therefore, the dimension of the panel structure is shrunk accordingly to satisfy the demand for electronic devices to be light, thin and compact. In addition, the panel structures 400 and 400′ of the embodiment provide implementation modes to satisfy different process demands.

According to the panel structure and the manufacturing method thereof disclosed in the above embodiments of the invention, ZnO is used to be the material of the transistors of at least one of the control circuit and the display circuit, so that the circuit to which the transistor belongs has high mobility. Therefore, the dimension of the panel structure can be shrunk accordingly. In addition, different implementation modes are presented in the above-mentioned embodiments to satisfy different process demands.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A panel structure disposed in a display device, the panel structure comprising:
a substrate having a display circuit and a control circuit;
a plurality of first transistors disposed at the display circuit of the substrate, wherein each of the first transistors has a first active layer; and
a plurality of second transistors disposed at the control circuit of the substrate, wherein each of the second transistors has a second active layer, and the materials of at least one of the first active layer and the second active layer comprise ZnO.

2. The panel structure according to claim 1, wherein the control circuit comprises a signal control circuit and a scan control circuit, and the panel structure further comprises:
a plurality of third transistors disposed at the control circuit of the substrate, wherein each of the third transistors has a third active layer;
wherein, the second transistors are disposed at one of the signal control circuit and the scan control circuit, and the third transistors are disposed at the other one of the signal control circuit and the scan control circuit.

3. The panel structure according to claim 2, wherein structures of the second transistors and structures of the third transistors are the same.

4. The panel structure according to claim 2, wherein materials of the first active layer comprise ZnO, and materials of both the second active layer and the third active layer are ZnO or amorphous silicon (a-Si).

5. The panel structure according to claim 2, wherein materials of the second active layer comprise ZnO, and materials of both the first active layer and the third active layer are ZnO or amorphous silicon.

6. The panel structure according to claim 1, further comprising:
an insulation layer disposed on the substrate.

7. The panel structure according to claim 6, wherein each of the first transistors has a first gate and a first island structure, the first gate corresponds to the first island structure, the first gate is disposed between the substrate and the insulation layer, and the first island structure is disposed on the insulation layer.

8. The panel structure according to claim 7, wherein the first island structure has a first electrode layer, a first opening, a first ohm contact layer and the first active layer, the first active layer and the first ohm contact layer are sequentially disposed on the insulation layer, a part of the first electrode layer is disposed on the first ohm contact layer, another part of the first electrode layer is disposed on the insulation layer, and the first opening penetrates the first electrode layer and the first ohm contact layer and exposes the first active layer.

9. The panel structure according to claim 7, wherein each of the second transistors has a second gate and a second island structure, the second island structure corresponds to the second gate, the second island structure has a second electrode layer, a second opening and the second active layer, the second opening penetrates the second electrode layer, and the second active layer is disposed with respect to the second electrode layer.

10. The panel structure according to claim 9, wherein the second gate is disposed between the substrate and the insulation layer, and the second island structure is disposed on the insulation layer.

11. The panel structure according to claim 10, wherein the second electrode layer is disposed on the insulation layer, the second opening penetrates the second electrode layer and exposes the insulation layer, and the second active layer covers the second opening.

12. The panel structure according to claim 11, wherein each of the second transistors further has a second ohm contact layer, the second ohm contact layer is disposed on the second electrode layer, and the second opening also penetrates the second ohm contact layer.

13. The panel structure according to claim 10, wherein the second active layer is disposed on the insulation layer, the second electrode layer is disposed above the second active layer, and the second opening penetrates the second electrode layer and exposes the second active layer.

14. The panel structure according to claim 13, wherein each of the second transistors further has a second ohm contact layer, the second ohm contact layer is disposed between the second active layer and the second electrode layer, and the second opening also penetrates the second ohm contact layer.

15. The panel structure according to claim 9, wherein the second gate is disposed on the insulation layer, and the second island structure is disposed between the insulation layer and the substrate.

16. The panel structure according to claim 15, wherein the second electrode layer is disposed on the substrate, the second opening penetrates the second electrode layer and exposes the substrate, and the second active layer covers the second opening.

17. The panel structure according to claim 16, wherein each of the second transistors further has a second ohm contact layer, each of the first transistors further has a metal oxidation layer, the second ohm contact layer is disposed on the second electrode layer, the metal oxidation layer is disposed on the first gate, and the second opening also penetrates the second ohm contact layer.

18. The panel structure according to claim 15, wherein the second active layer is disposed on the substrate, a part of the second electrode layer is disposed above the second active layer, another part of the second electrode layer is disposed on the substrate, and the second opening penetrates the second electrode layer and exposes the second active layer.

19. The panel structure according to claim 18, wherein each of the second transistors further has a second ohm contact layer, each of the first transistors further has a metal oxidation layer, the second ohm contact layer is disposed between the second active layer and the second electrode layer and the substrate, the metal oxidation layer is disposed between the first gate and the substrate, and the second opening also penetrates the second ohm contact layer.

20. The panel structure according to claim 6, further comprising:
a pixel electrode electrically connected to the first transistors.

21. The panel structure according to claim 20, further comprising:
a passivation layer covering the first transistors and the second transistors.

22. A manufacturing method of a panel structure, comprising:
(a) providing a substrate; and
(b) forming a plurality of first transistors at the substrate to constitute a display circuit, and forming a plurality of second transistors at the substrate to constitute a control circuit, wherein each of the first transistors has a first active layer, each of the second transistors has a second active layer, and materials of at least one of the first active layer and the second active layer comprise ZnO.

23. The manufacturing method according to claim 22, wherein the control circuit comprises a signal control circuit and a scan control circuit, and the step (b) further comprises:
forming a plurality of third transistors at the control circuit of the substrate, wherein each of the third transistors has a third active layer;
wherein, the second transistors are disposed at one of the signal control circuit and the scan control circuit, and the third transistors are disposed at the other one of the signal control circuit and the scan control circuit.

24. The manufacturing method according to claim 23, wherein structures of the second transistors and structures of the third transistors are the same.

25. The manufacturing method according to claim 23, wherein materials of the first active layer comprise ZnO, and materials of both the second active layer and the third active layer are ZnO or amorphous silicon.

26. The manufacturing method according to claim 23, wherein materials of the second active layer comprise ZnO, and materials of both the first active layer and the third active layer are ZnO or amorphous silicon.

27. The manufacturing method according to claim 22, wherein the step (b) further comprises:
(b1) forming a first gate of each of the first transistors on the substrate, and forming a second gate of each of the second transistors on the substrate;
(b2) forming an insulation layer on the first gate, the second gate and the substrate; and
(b3) sequentially forming the first active layer and a material layer of a first ohm contact layer on the insulation layer.

28. The manufacturing method according to claim 27, wherein after the step (b3), the step (b) further comprises:
(b4) forming a first electrode layer on the material layer of the first ohm contact layer and the insulation layer, and forming a second electrode layer on the insulation layer, wherein the first electrode layer has a first opening, and the second electrode layer has a second opening;
(b5) etching the material layer of the first ohm contact layer at the first opening to form the first ohm contact layer; and
(b6) forming the second active layer to cover the second opening.

29. The manufacturing method according to claim 28, wherein after the step (b4) and before the step (b5), the step (b) further comprises:
(b41) forming a second ohm contact layer on the second electrode layer.

30. The manufacturing method according to claim 27, wherein after the step (b3), the step (b) further comprises:
(b4) forming the second active layer on the insulation layer;
(b5) forming a first electrode layer on the material layer of the first ohm contact layer and the insulation layer, and forming a second electrode layer above the second active layer, wherein the first electrode layer has a first opening, and the second electrode layer has a second opening; and
(b6) etching the material layer of the first ohm contact layer at the first opening to form the first ohm contact layer.

31. The manufacturing method according to claim 30, wherein after the step (b4) and before the step (b5), the step (b) further comprises:
(b41) forming a second ohm contact layer on the second active layer.

32. The manufacturing method according to claim 22, wherein the step (b) further comprises:
(b1) forming a first gate of each of the first transistors on the substrate, and forming a second electrode layer of each of the second transistors on the substrate, wherein the second electrode layer has a second opening;
(b2) forming the second active layer to cover the second opening;
(b3) forming an insulation layer above the first gate, the second electrode layer, the second active layer and the substrate;
(b4) sequentially forming the first active layer and a material layer of a first ohm contact layer on the insulation layer;
(b5) forming a first electrode layer on the material layer of the first ohm contact layer and the insulation layer, and forming a second gate on the insulation layer, wherein the first electrode layer has a first opening; and
(b6) etching the material layer of the first ohm contact layer at the first opening to form the first ohm contact layer.

33. The manufacturing method according to claim 32, wherein the step (b1) further comprises:
forming a second ohm contact layer on the second electrode layer, and forming a metal oxidation layer on the first gate, wherein the second opening also penetrates the second ohm contact layer.

34. The manufacturing method according to claim 22, wherein the step (b) further comprises:
(b1) forming the second active layer on the substrate;
(b2) forming a first gate of each of the first transistors above the substrate, and forming a second electrode layer above a part of the second active layer and a part of the substrate, wherein the second electrode layer has a second opening;
(b3) forming an insulation layer on the first gate, the second electrode layer, the second active layer and the substrate;
(b4) sequentially forming the first active layer and a material layer of a first ohm contact layer on the insulation layer;
(b5) forming a first electrode layer on the material layer of the first ohm contact layer and the insulation layer, and forming a second gate on the insulation layer, wherein the first electrode layer has a first opening; and
(b6) etching the material layer of the first ohm contact layer at the first opening to form the first ohm contact layer.

35. The manufacturing method according to claim 34, wherein the step (b2) further comprises:
forming a second ohm contact layer between the second electrode layer and the second active layer and the substrate, and forming a metal oxidation layer between the first gate and the substrate, wherein the second opening also penetrates the second ohm contact layer.

36. The manufacturing method according to claim 22, further comprising:
forming a pixel electrode to electrically connect the first transistors.

37. The manufacturing method according to claim 36, further comprising:
forming a passivation layer to cover the first transistors and the second transistors.
